(19) United States
(12) Patent Application Publication
(10) Pub. No.: US 2010/0216305 A1
(43) Pub. Date: Aug. 26, 2010

(54) METHOD FOR FABRICATING SEMICONDUCTOR DEVICE

(76) Inventor: Junichi WADA, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/614,086

(22) Filed: Nov. 6, 2009

(30) Foreign Application Priority Data
Feb. 26, 2009 (JP) 2009-043381

(51) Int. Cl. H01L 21/3205

(52) U.S. Cl. 438/655; 438/656; 257/E21.295; 257/E21.296

(57) ABSTRACT

A method for fabricating a semiconductor device, includes forming a dielectric film above a substrate; forming an opening in the dielectric film; forming a ruthenium (Ru) film at least on a bottom surface of the opening; and filling in the opening with a tungsten (W) film in which the Ru film is formed, according to a chemical vapor deposition (CVD) method by hydrogen (H₂) reduction.

### CROSS-REFERENCE TO RELATED APPLICATION

This application is based upon and claims the benefit of priority from prior Japanese Patent Application No. 2009-043381 filed on Feb. 26, 2009 in Japan, the entire contents of which are incorporated herein by reference.

### BACKGROUND OF THE INVENTION

1. Field of the Invention

The present invention relates to a method for fabricating a semiconductor device. For example, the present invention relates to a method for forming a plug using tungsten (W) as a plug material.

2. Related Art

As LSI becomes finer, an increase in resistance of a contact portion connecting a semiconductor substrate and a wire poses a problem. Conventionally, a tungsten (W) plug is used as a metallic contact. W is filled into a contact hole by reducing, for example, tungsten hexafluoride (WF₆) by hydrogen (H₂) by the chemical vapor deposition (CVD) method and an excess W film is removed by the chemical-mechanical polishing (CMP) method, whereby a W plug is formed. However, with W-CVD using WF₆ as a source gas and H₂ as a reducing gas, WF₆ does not decompose on a dielectric film at a low temperature of the process upper limit temperature or below (450° C. or below), the limit temperature being defined by the aggregation temperature of salicide or the like, and thus, it is difficult to form a W film. Therefore, a laminated film made of titanium (Ti) and titanium nitride (TiN) is formed inside a contact hole as liner materials in most cases.

Here, although a Ti/TiN film used as a liner film is a conductive film, it is difficult to receive electrons because a native oxide is present on the surface thereof, and thus it is difficult to decompose WF₆ by a reduction reaction even when the Ti/TiN is provided. Therefore, an SiHx layer is formed by adsorption by silane (SiH₄) reduction on a conventional Ti/TiN liner film whose surface is oxidized. Then, an initial film of W is formed by causing WF₆ decomposition by electrons supplied from the SiHx layer. However, a large amount of Si is contained as impurities in the initial film of W obtained by the SiH₄ reduction, resulting in a film having high specific resistance more than 200 μΩcm. Thus, generally an initial film of W is formed on the substrate surface by the SiH₄ reduction and then, a W film is formed by the H₂ reduction to lower resistance (see Published Unexamined Japanese Patent Application (Translation of PCT Application) No. 2001-524261, for example).

Or, an initial W film may be formed by using B₂H₆ instead of using SiH₄ as a reducing gas, but boron (B) is mixed as impurities into the initial film of W this time. As a result, the specific resistance cannot be lowered than about 160 μΩcm.

Thus, as described above, impurities are mixed into the W film regardless of the SiH₄ reduction or B₂H₆ reduction, making the specific resistance much higher than 15 μΩcm obtained by a W film formed by the H₂ reduction. The ratio occupied by an initial film of W with high specific resistance inside a contact hole increases as LSI becomes finer in recent years and therefore, a problem that contact resistance cannot be lowered arises. Further, a TiN film formed as a liner also has high specific resistance and thus, the presence of a TiN film is a cause why contact resistance cannot be lowered.

The problem of an initial film of W with high specific resistance is not limited to the above contact plug and a similar problem arises in a wire or a via plug using W.

### BRIEF SUMMARY OF THE INVENTION

In accordance with one aspect of the present invention, a method for fabricating a semiconductor device is provided, which includes forming a dielectric film above a substrate; forming an opening in the dielectric film; forming a ruthenium (Ru) film at least on a bottom surface of the opening; and filling in the opening with a tungsten (W) film in which the Ru film is formed, according to a chemical vapor deposition (CVD) method by hydrogen (H₂) reduction.

### BRIEF DESCRIPTION OF THE DRAWINGS

FIG. 1 is a flow chart showing principal parts of a method for fabricating a semiconductor device according to a first embodiment.

FIGS. 2A to 2D are process sectional views showing processes performed conforming to the flow chart in FIG. 1.

FIGS. 3A to 3C are process sectional views showing processes performed conforming to the flow chart in FIG. 1.

FIG. 4 is a diagram showing the flow of two steps performed at different temperatures according to the first embodiment.

FIG. 5 is a process sectional view showing a process performed conforming to the flow chart in FIG. 1.

FIG. 6 is a flow chart showing principal parts of the method for fabricating a semiconductor device according to a second embodiment.

FIG. 7 is a diagram exemplifying the supply flow of a WF₆ gas and an H₂ gas according to the second embodiment.

FIG. 8 is a flow chart showing principal parts of the method for fabricating a semiconductor device according to a third embodiment.

FIG. 9 is a conceptual diagram exemplifying a continuous vacuum apparatus according to the third embodiment.

FIGS. 10A and 10B are process sectional views showing processes performed conforming to the flow chart in FIG. 8.

### DETAILED DESCRIPTION OF THE INVENTION

In each embodiment below, a method for fabricating a semiconductor device by which a plug or wire of a W film having lower specific resistance than before is obtained will be described. A case in which a contact plug is formed will be described in each embodiment, but each embodiment is not limited to the contact plug and may be applied when a wire or a via plug is formed.

### FIRST EMBODIMENT

A first embodiment will be described below using drawings.

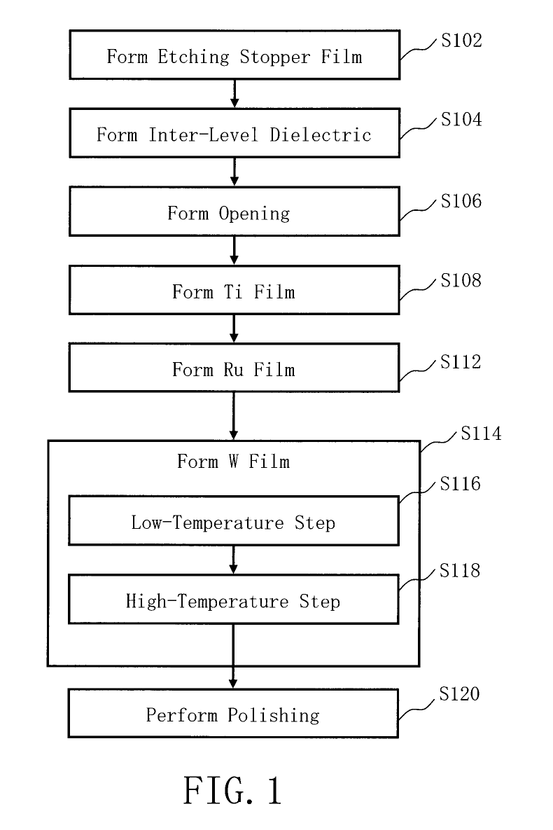

FIG. 1 is a flow chart showing principal parts of a method for fabricating a semiconductor device according to the first embodiment. In FIG. 1, in the method for fabricating a semiconductor device according to the present embodiment, a series of processes including an etching stopper film formation process (S102), an inter-level dielectric formation process (S104), opening formation process (S106), titanium (Ti) film formation process (S108), ruthenium (Ru) film formation process (S112), tungsten (W) film formation process (S114), and polishing process (S120) are performed. Also, in the method, a series of processes including a low-temperature process (S116) and high-temperature process (S118) are performed as internal processes of the tungsten (W) film formation process (S114). The etching stopper film formation process (S102) may be skipped. In the following embodiments, a case in which a series of processes includes the etching stopper film formation process (S102) is described, however the present embodiment is not limited to such a case.

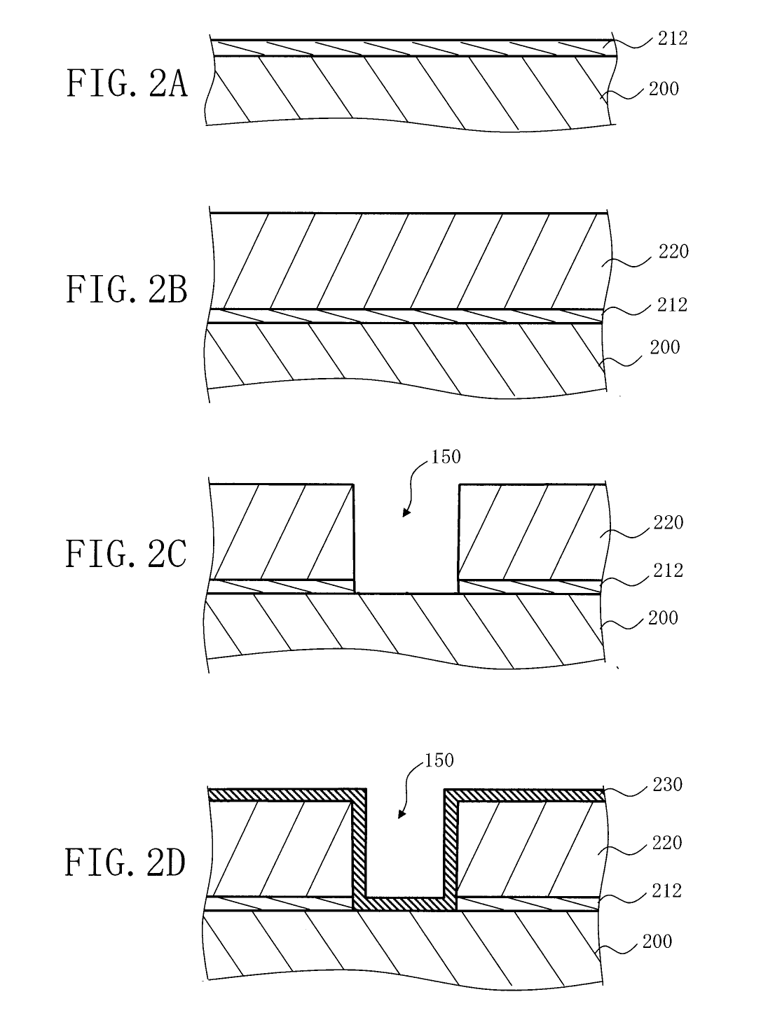

FIGS. 2A to 2D are process sectional views showing processes performed conforming to the flow chart in FIG. 1. FIGS. 2A to 2D show the etching stopper film formation process (S102) to the titanium (Ti) film formation process (S108) in FIG. 1. Subsequent processes will be described later.

In FIG. 2A, as the etching stopper film formation process (S102), an etching stopper film 212 of 50 nm, for example, is formed on the surface of a semiconductor substrate 200 on which device portions such as a substrate diffusion layer and gate electrode are formed, by the CVD (chemical vapor deposition) method. Silicon nitride (SiN), silicon carbonitride (SiCN), silicon oxynitride (SiON), or the like may be suitably used as a material of the etching stopper film 212. A silicon wafer having a diameter of 300 mm, for example, is used as the substrate 200. Here, device portions are not illustrated.

In FIG. 2B, as the inter-level dielectric formation process (S104), an inter-level dielectric 220 of 150 nm, for example, is formed on the etching stopper film 212. A silicon oxide (SiO₂) film or low-k film is suitably used as the inter-level dielectric 220. Particularly, if a low-k film formed of a porous low dielectric constant material is used as the inter-level dielectric 220, an inter-level dielectric having relative dielectric constant k lower than 3.5 can be obtained. For example, a low-k film is formed by using a film having polymethyl siloxane as a component, which is a low dielectric constant material having relative dielectric constant less than 2.5. In addition to polymethyl siloxane, for example, a low-k film may be formed by using a material of at least one film selected from a group including: a film having siloxane backbone structures such as polysiloxane, hydrogen silsesquioxane, and methyl silsesquioxane; a film having organic resin as a main component such as polyarylene ether, polybenzo oxazole, and polybenzo cyclobutene; and a porous film such as a porous silica film, for example. Using such a material of a low-k film, a low dielectric constant of less than 2.5 can be obtained. As a formation method thereof, for example, the SOD (spin on dielectric coating) method for forming a thin film by spin coating of a solution and heat treatment can be used. For example, a low-k film can be formed by forming a film by a spinner, baking a wafer, on which the film is formed, on a hot plate in a nitrogen atmosphere, and finally curing the wafer on the hot plate at temperature higher than the baking temperature in the nitrogen atmosphere. A porous dielectric film having predetermined property values can be obtained by appropriately adjusting the low-k material and formation conditions. Alternatively, a low-k film may be formed by the CVD method. When an SiO₂ film is formed as the inter-level dielectric 220, the CVD method is suitably used to form the inter-level dielectric 220.

When a low-k film is formed as the inter-level dielectric 220, a cap dielectric film (not shown) is suitably formed to form a two-layer structure. For example, a cap dielectric film may be formed by the CVD method. By forming a cap dielectric film, a low-k film having weak mechanical strength can be protected. A cap dielectric film is suitably formed by using, as a material for a cap dielectric film, at least one dielectric material having relative dielectric constant of 2.5 or more selected from a group including: silicon carboxide (SiOC), TEOS (tetraethoxy silane), SiC, silicon carbohydrate (SiCH), silicon carbonitride (SiCN), and SiOCH. Other methods than the CVD method may also be used as the formation method.

In FIG. 2C, as the opening formation process (S106), an opening 150, which functions as a contact hole in lithography and dry etching processes, is formed in the inter-level dielectric 220. The opening 150 may be formed by removing the exposed inter-level dielectric 220 from the substrate 200 having a resist film formed on the inter-level dielectric 220 through the lithography process such as a resist application process and exposure process, which are not shown, by the anisotropic etching method using the etching stopper film 212 as an etching stopper. Then, the exposed etching stopper film 212 may be removed. By using the anisotropic etching method, the opening 150 can be formed substantially perpendicularly to the surface of the substrate 200. For example, the opening 150 may be formed by the reactive ion etching method.

In FIG. 2D, as the Ti film formation process (S108), a Ti film 230 is formed on the surface of the opening 150 formed by the opening formation process and on the surface of the inter-level dielectric 220. The Ti film 230 of 20 nm, for example, is formed. The Ti film 230 is formed by using the plasma CVD method, for example. A mixed gas of titanium tetrachloride (TiCl₄), hydrogen (H₂), and argon (Ar) is made to flow and pressure inside a chamber and substrate temperature are set to predetermined values to generate plasma between counter electrodes of the substrate. By reducing TiCl₄ by H₂ in this manner, the Ti film 230 can be formed. The formation method is not limited to the CVD method and the sputter process, which is a kind of the physical vapor deposition (PVD) method, or the atomic layer deposition (ALD or the atomic layer chemical vapor deposition (ALCVD)) method may also be used. With respect to Ti film 230 formed at the bottom of the opening 150, an oxide film of the substrate 200 formed at the bottom of the opening 150 is reduced by Ti so as to form a titanium silicide (TiSi₂). Accordingly, an ohmic contact can be secured. Thus, the Ti film 230 is not necessarily formed on sidewalls and the bottom surface of the opening 150 as far as the Ti film 230 is formed at least on the bottom surface.

The first embodiment is described by taking a case in which Ti having high reductive properties is formed as an example, but a material having high reductive properties is not limited to Ti and any material having high reductive properties may be used. For example, hafnium (Hf) may be used.

When a film of Ti or the like is thickly formed on sidewalls of the opening 150, resistance of the contact plug rises. Thus, it is preferable to select a film formation method for forming a Ti film thickly at a contact bottom, but not thickly on hole sidewalls using PVD and PECVD having high directivity.

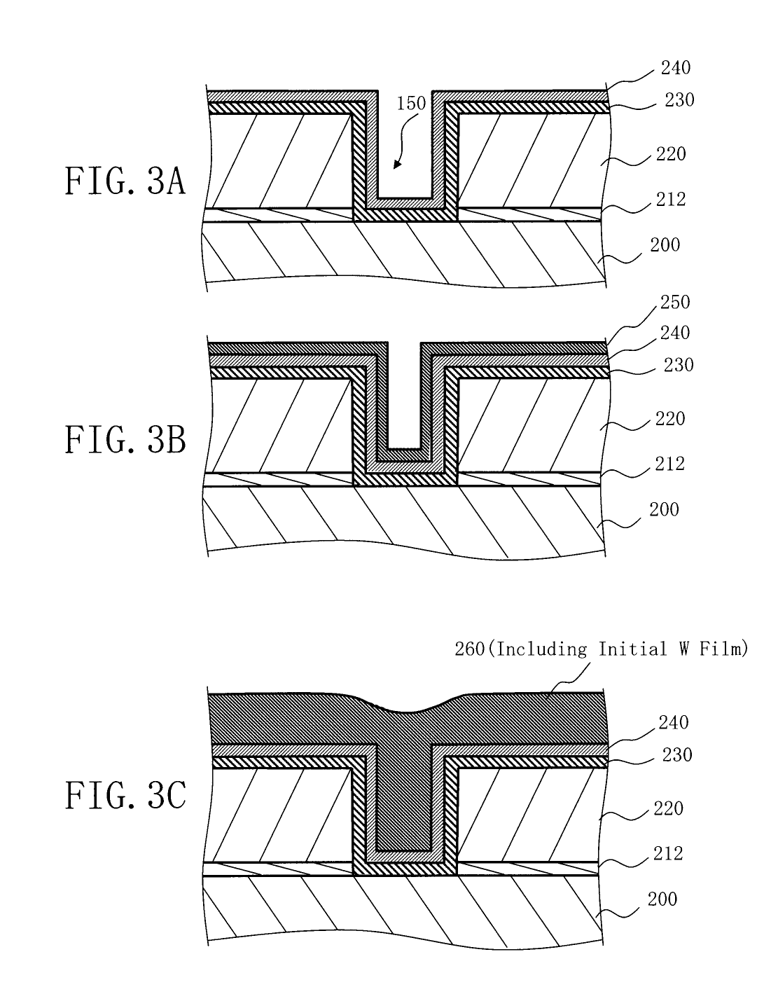

FIGS. 3A to 3C are process sectional views showing processes performed conforming to the flow chart in FIG. 1. FIGS. 3A to 3C show the ruthenium (Ru) film formation process (S112) to the tungsten (W) film formation process (S114) in FIG. 1. Subsequent processes will be described later.

In FIG. 3A, as the ruthenium (Ru) film formation process (S112), an Ru film 240 is formed on the surface of the opening 150 and the substrate 200 where the Ti film 230 is formed. The Ru film 240 having a thickness of 1 to 5 nm, for example, is formed. Preferably, the Ru film 240 having a thickness of 2 to 3 nm is formed. The Ru film 240 is formed by, for example, the CVD method. The Ru film 240 is formed directly on the Ti film 230.

In contrast to TiN, Ru retains conductivity even when oxidized. Further, even if a surface oxide layer is formed when Ru is exposed to the air, a reduction reaction of WF₆by H₂ proceeds. Therefore, by using Ru, a W film can be directly formed by the H₂ reduction without using a reducing gas such as SiH₄ and B₂H₆ that leaves impurities behind, as described later. Ru has higher surface free energy than TiN, and thus is more likely to generate growth nuclei for forming a W film. This means that film growth by the CVD method is facilitated. Because growth nuclei are more likely to be generated, W can be formed as a uniform film, instead of being formed as islands. Thus, a W film can be directly formed by the reduction of H₂ having lower specific resistance without forming a W film containing Si or B having higher specific resistance. Therefore, contact resistance can be significantly lowered.

Since, as described above, a W film formed by the H₂ reduction grows directly on the Ru film 240, the Ru film 240 is not necessarily formed on sidewalls and the bottom surface of the opening 150 as far as the Ru film 240 is formed at least on the bottom surface. If the Ru film 240 is formed on the bottom surface, the opening 150 can be buried upward from the bottom. Further, Ru has specific resistance of 20-40 μΩcm, which is significantly lower than that of TiN. Therefore, compared with a case of forming a TiN film, contact resistance can be further lowered. Thus, as described above, the Ru film 240 can lower contact resistance by being formed directly on the Ti film 230, instead of via a TiN film.

Here, an Ru oxide layer (RuO layer) also has higher surface free energy than TiN and generates W growth nuclei, but has higher specific resistance than pure Ru and thus, it may become difficult to supply electrons necessary for WF₆ decomposition. Therefore, while thin native oxide formed on pure Ru when exposed to the air poses no problem, a thick Ru oxide layer could make decomposition of WF₆ difficult. Particularly, Ru oxide has the absolute value of standard generation energy smaller than that of Si, and thus if Ru oxide is brought into contact with Si exposed at the contact bottom or metal silicide without forming a metallic liner film of Ti or the like, the Ru oxide is reduced by heat treatment in a subsequent process, leading to generation of SiO₂ having very high specific resistance on Si or metal silicide, which causes a problem that contact resistance becomes high.

If, on the other hand, the contact bottom is cleaned by wet cleaning or dry cleaning, SiO₂ still remains slightly on Si or metal silicide. Thus, according to the first embodiment, a metallic liner film of Ti or the like having an absolute value of standard generation energy larger than that of Si to reduce the SiO₂. However, if an Ru oxide layer and a liner layer come into contact, oxide such as TiO₂ having very large specific resistance is generated, which also causes a problem that contact resistance becomes high.

As described above, it is necessary to have a structure in which Ru oxide does not come into contact directly with the contact bottom or liner film. According to the first embodiment, by using Ru itself instead of Ru oxide (RuO), a structure, in which RuO does not come into contact directly with the contact bottom or the Ti film 230 even if native oxide of RuO is formed on the upper surface of the Ru film 240, can be obtained.

Next, as the W film formation process (S114), a W film is formed inside the opening 150 and on the surface of the substrate 200 where the Ru film 240 is formed to fill in the opening 150 with the W film. According to the first embodiment, a W film is formed in two steps in which the temperature is switched from a low temperature to a high temperature.

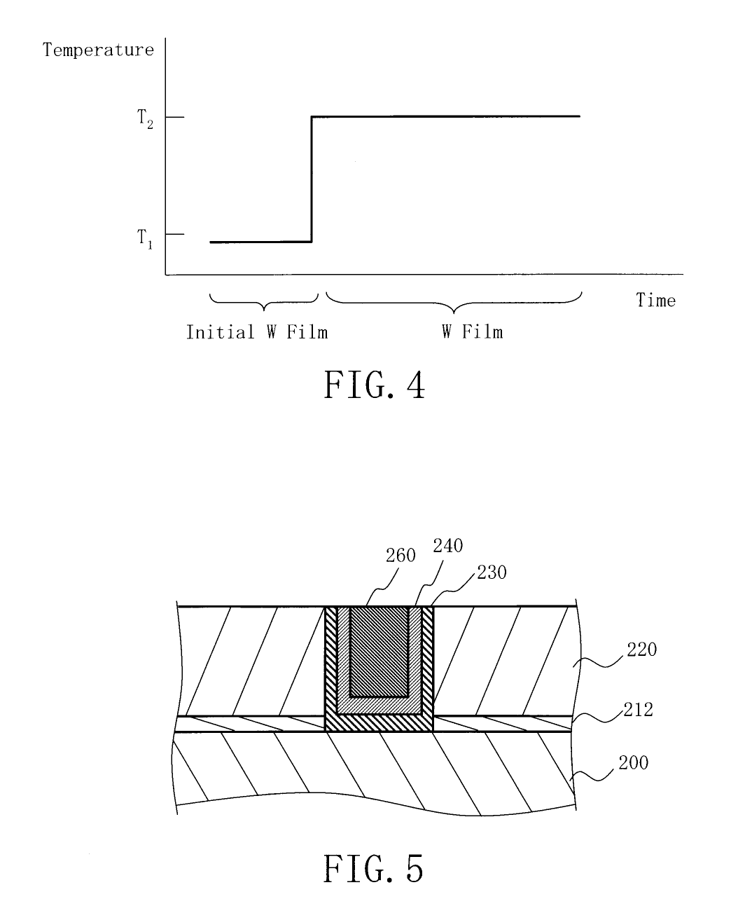

FIG. 4 is a diagram showing the flow of two steps performed at different temperatures according to the first embodiment. In FIG. 4, an initial W film is formed at a lower temperature T1, and then a remaining W film is formed at a higher temperature T2 at high speed.

In FIG. 3B, as the low-temperature process (S116) of the W film formation process (S114), an initial W film 250 (a portion of a W film) is formed, or “deposited” at the temperature T1 (first temperature) between 250° C. and 350° C. inside the opening 150 and on the surface of the substrate 200 where the Ru film 240 is formed. The initial W film 250 is formed by directly reducing WF₆ by H₂ according to the CVD method without using a reducing gas that leaves impurities such as SiH₄ and B₂H₆. That is, a WF₆ gas and an H₂ gas are supplied to form or “deposit” the initial W film 250 at temperature between 250° C. and 350° C. Because of the presence of the Ru film 240, as described above, WF₆ receives electrons from the Ru film 240 on the substrate to proceed a reduction reaction, causing a reaction WF₆+3H₂−>W+6HF on the surface of the Ru film 240. The initial W film 250 may be formed to the extent that the whole surface of the Ru film 240 inside the opening 150 is covered. By maintaining the temperature between 250° C. and 350° C., corrosion of Ru by fluorine (F) as a result of decomposition in the initial stage of film formation can be prevented or suppressed. If the Ru film 240 is not formed over the entire sidewalls of the opening 150 and thus, the Ti film 230 is exposed some portion inside the opening 150, the initial W film 250 may be formed to the extent that the whole surface of the Ti film 230 and the Ru film 240 inside the opening 150 is covered.

In FIG. 3C, as the high-temperature process (S118) of the W film formation process (S114), subsequent to the formation of the initial W film 250, the temperature is increased to the temperature T2 (second temperature) of about 400° C., for example, and at the temperature, a W film 260 (remainder of the W film) is formed or “deposited” inside the opening 150 and on the surface of the substrate 200 where the initial W film 250 is formed. Accordingly, the whole opening 150 is filled in with the W film 260. By increasing the temperature from when the initial W film 250 is formed, the film formation speed can be increased. From the viewpoint of suppressing deterioration of characteristics in device portions of the substrate 200, the W film 260 is preferably formed at temperature between 400° C. and 500° C.

Thus, as described above, the W film 260 can be formed in a shorter time while suppressing corrosion by F by forming the W film 260 in two steps in which the temperature is switched from a low temperature to a high temperature. According to the first embodiment, compared with a conventional case in which an initial W film is formed on a Ti/TiN film using a reducing gas that leaves impurities behind such as SiH₄ and B₂H₆ and then a remaining W film is formed by the H₂ reduction, throughput can be improved.

FIG. 5 is a process sectional view showing a process performed conforming to the flow chart in FIG. 1. In FIG. 5, the polishing process (S120) is shown.

In FIG. 5, as the polishing process (S120), the excessive W film 260 (a portion of the W film 260) including the initial W film 250 formed out of the opening 150 of the substrate 200, the excessive Ru film 240 (a portion of the Ru film 240), and the excessive Ti film 230 (a portion of the Ti film 230) are polished for planarization. Accordingly, the contact plug of W shown in FIG. 5 can be formed.

Thus, a plug of a W film having lower specific resistance than before can be obtained by forming a W film on the Ru film 240, as described above.

### SECOND EMBODIMENT

According to a second embodiment, a case, in which treatment to remove an RuO film on the surface of an Ru film is carried out using a gas used when a W film is formed, will be described.

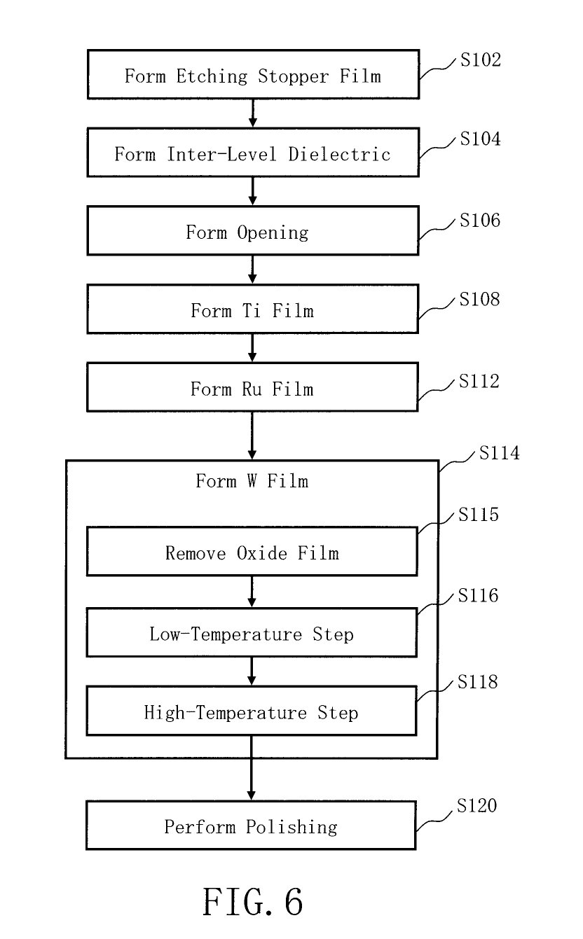

FIG. 6 is a flow chart showing principal parts of the method for fabricating a semiconductor device according to the second embodiment. In FIG. 6, the method for fabricating a semiconductor device according to the second embodiment is the same as that in FIG. 1 except that an oxide film removal process (S115) is added before the low-temperature process (S116) as an internal process of the tungsten (W) film formation process (S114). Thus, content of each process from the etching stopper film formation process (S102) to the Ru film formation process (S112) is the same as that according to the first embodiment.

As the oxide film removal process (S115), RuO such as native oxide formed on the upper surface of the Ru film 240 is removed from the state shown in FIG. 3A. More specifically, H₂ is used, which serves as a reducing gas when a W film is formed by the CVD method.

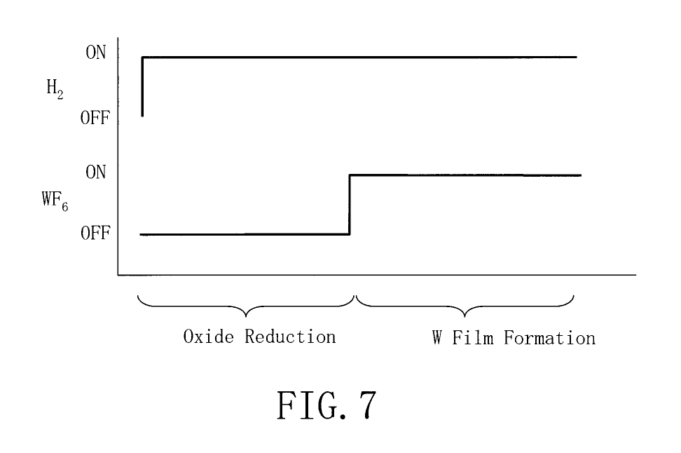

FIG. 7 is a diagram exemplifying the supply flow of a WF₆ gas and an H₂ gas according to the second embodiment. In FIG. 7, as the oxide film removal process (S115), an H₂ gas is supplied to remove RuO such as native oxide formed on the surface of the Ru film 240 by reduction. The temperature is preferably 200° C. or higher. For example, the temperature may be 250° C. to 350° C., which is a temperature set for the subsequent low-temperature process (S116). Then, as the subsequent low-temperature process (S116) and high-temperature process (S118), a WF₆ gas is supplied in addition to the H₂ gas to form the W film 260. When the W film 260 is formed, the W film 260 is formed in two steps in which the temperature is switched from a low temperature to a high temperature similarly to the first embodiment. Also, subsequent processes are the same as those according to the first embodiment.

According to the second embodiment, RuO formed on the upper surface of the Ru film 240 is removed and thus, specific resistance of the Ru film 240 can further be lowered. Therefore, when compared with the first embodiment, contact resistance can be lowered still further.

### THIRD EMBODIMENT

While a case in which a laminated film of the Ti film 230 and the Ru film 240 is used is described according to the first embodiment, a case in which the Ru film 240 is formed directly on the substrate 200 without using the Ti film 230 will be described according to a third embodiment.

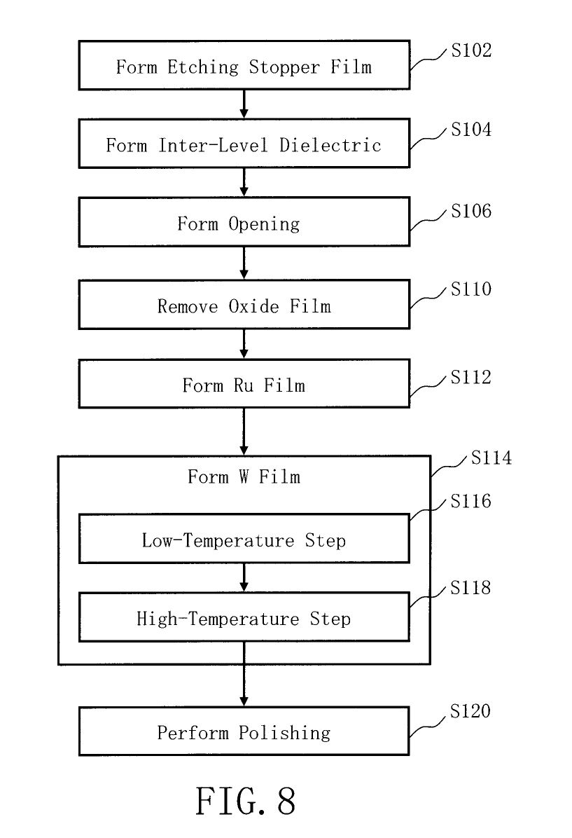

FIG. 8 is a flow chart showing principal parts of the method for fabricating a semiconductor device according to the third embodiment. In FIG. 8, the method for fabricating a semiconductor device according to the third embodiment is the same as that in FIG. 1 except that an oxide film, removal process (S110) is added instead of the Ti film formation process (S108). Thus, content of each process from the etching stopper film formation process (S102) to the opening formation process (S106) is the same as that according to the first embodiment.

An oxide film is formed inside the opening 150 before the Ru film is formed, particularly on the substrate 200 at the bottom of the opening 150. Thus, according to the first embodiment described above, ohmic contact is secured by removing an oxide film on the substrate 200 formed at the bottom of the opening 150 by reducing the oxide film by Ti. However, if, for example, the Ru film 240 can be formed in a state in which an oxide film on the substrate 200 is removed by performing cleaning processing of the contact bottom in continuous vacuum, the Ti film 230 can be eliminated.

Thus, as the oxide film removal process (S110), an oxide film (SiO₂) on the substrate 200 is removed in a vacuum atmosphere before the Ru film is formed. SiO₂ is removed by a reverse sputter process, for example. Or, it is also preferable to remove SiO₂ by supplying an F gas as chemical dry treatment.

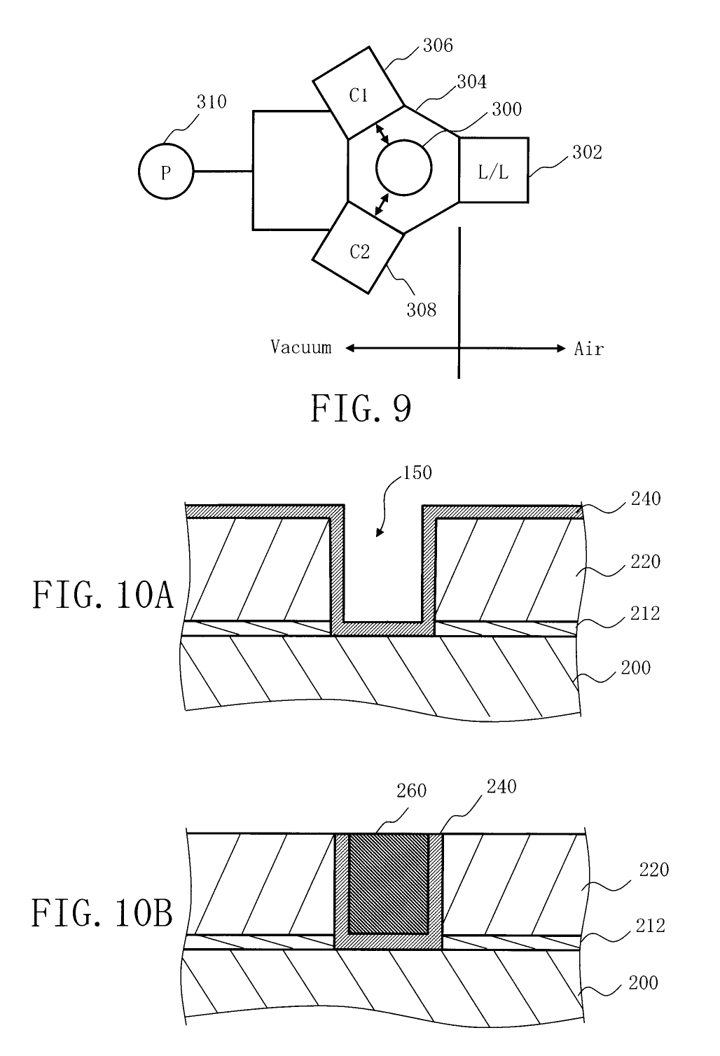

FIG. 9 is a conceptual diagram exemplifying a continuous vacuum apparatus according to the third embodiment. In FIG. 9, a substrate 300 arranged in a load locks (L/L) chamber 302 is transferred into a transfer chamber 304 evacuated by a vacuum pump 310 and first arranged in a chamber 306 (C1). Then, as the oxide film removal process (S110), an oxide film (SiO₂) on the substrate 200 is removed in the chamber 306 kept in the vacuum atmosphere. Then, the substrate 300 is transferred into a chamber 308 (C2) continuously kept in the vacuum atmosphere without being exposed to the air via the transfer chamber 304 before being arranged therein. Then, as the Ru film formation process (S112), after the oxide film on the substrate 200 is removed, the Ru film 240 is formed in the continuous vacuum atmosphere without being exposed to the air.

FIGS. 10A and 10B are process sectional views showing processes performed conforming to the flow chart in FIG. 8. FIGS. 10A and 10B show states after the Ru film formation process (S112) and the polishing process (S120) in FIG. 8 respectively.

After the Ru film formation process (S112), as shown in FIG. 10A, the Ru film 240 is formed at least on the substrate 200 at the bottom of the opening 150 directly instead of via the Ti film 230. Each subsequent process is the same as that according to the first embodiment and after the polishing process (S120), planarization is accomplished and a contact plug is complete, as shown in FIG. 10B.

In the foregoing, embodiments have been described with reference to concrete examples. However, the present invention is not limited to such concrete examples. For example, when a wire or via plug of W is formed, as shown according to the third embodiment, the W film 260 (including the initial W film 250) may be formed after the Ru film 240 is formed in the opening 150 without forming the Ti film 230. Accordingly, compared with a case in which a TiN film is formed on sidewalls and on the bottom surface of a W film, specific resistance can be lowered.

Concerning the thickness of inter-level dielectrics film and the size, shape, number and the like of openings, what is needed for semiconductor integrated circuits and various semiconductor elements can be selected and used as appropriate.

In addition, all semiconductor devices and methods for fabricating a semiconductor device that includes components of the present invention and can be obtained as modifications as appropriate by persons skilled in the art are included in the scope of the present invention.

While techniques normally used in the semiconductor industry such as a photolithography process and cleaning before and after treatment are not described for convenience of description, it is needless to say that such techniques are included in the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for fabricating a semiconductor device, comprising:
forming a dielectric film above a substrate;
forming an opening in the dielectric film;
forming a ruthenium (Ru) film at least on a bottom surface of the opening; and
filling in the opening with a tungsten (W) film in which the Ru film is formed, according to a chemical vapor deposition (CVD) method by hydrogen (H₂) reduction.

2. The method according to claim 1,
further comprising removing an oxide film formed on the bottom surface of the opening in a vacuum atmosphere before forming the Ru film,
wherein the Ru film is formed in the continuous vacuum atmosphere without being exposed to an air after removing the oxide film.

3. The method according to claim 1,
further comprising forming a titanium (Ti) film in the opening before forming the Ru film,
wherein the Ru film is formed directly on the Ti film.

4. The method according to claim 3,
wherein the Ru film is formed in such a way that Ru itself directly comes into contact with the Ti film, instead of via oxide.

5. The method according to claim 1,
wherein an oxide film is formed on an upper surface of the Ru film and
wherein when filling in the opening with the W film, the W film is deposited on the oxide film on the upper surface of the Ru film.

6. The method according to claim 1,
wherein an H₂ gas and a tungsten hexafluoride (WF₆) gas are supplied from a start to deposit the W film.

7. The method according to claim 6,
wherein when filling in the opening with the W film, control is exercised so that a temperature is changed in the middle of the filling while the H₂ gas and the tungsten hexafluoride (WF₆) gas are supplied.

8. The method according to claim 7,
wherein when filling in the opening with the W film, control is exercised so that the temperature is changed from a lower temperature to a higher temperature.

9. The method according to claim 8,
wherein the lower temperature is set at 250 to 350° C. and
the higher temperature is set at 400 to 500° C.

10. The method according to claim 8,
wherein when filling in the opening with the W film, control is exercised so that the temperature is changed after a portion of the W film is formed to an extent that a whole surface of the Ru film is covered.

11. The method according to claim 6,
wherein in filling in the opening with the W film, the tungsten hexafluoride (WF₆) gas is supplied after the H₂ gas is supplied.

12. The method according to claim 1,
wherein an oxide film is formed on an upper surface of the Ru film, the oxide film on the upper surface of the Ru film being removed after the Ru film is formed.

13. The method according to claim 12,
wherein when removing the oxide film on the upper surface of the Ru film, an H₂ gas is supplied.

14. The method according to claim 13,
wherein in filling in the opening with the W film, the H₂ gas that has been used for removing the oxide film on the upper surface of the Ru film continues to be used and also, a tungsten hexafluoride (WF₆) gas is supplied to deposit the W film.

15. The method according to claim 14,
wherein when filling in the opening with the W film, control is exercised so that the filling is started at a first temperature and the first temperature is changed to a second temperature in the middle of the filling and when removing the oxide film on the upper surface of the Ru film, a temperature for the removing is set to the first temperature.

16. The method according to claim 1,
wherein an oxide film is formed on an upper surface of the Ru film and the oxide film on the upper surface of the Ru film is a native oxide.

17. The method according to claim 1,
wherein when forming the Ru film, the Ru film is formed in such a way that Ru oxide is not contained at least at a bottom of the Ru film.

18. The method according to claim 17,
wherein silicon or silicide is contained on the bottom surface of the opening and the Ru film is formed in such a way that Ru itself directly comes into contact with the silicon or the silicide, instead of via oxide.

19. The method according to claim 1,
further comprising removing a portion of the W film and a portion of the Ru film formed out of the opening by polishing after filling in the opening with the W film.

20. The method according to claim 19,
further comprising forming a titanium (Ti) film in the opening before forming the Ru film,
wherein when removing by polishing, the portion of the W film, the portion of the Ru film, and a portion of the Ti film formed out of the opening are removed by polishing.
